(19) United States
(12) Patent Application Publication
(10) Pub. No.: US 2006/0051623 A1
(43) Pub. Date: Mar. 9, 2006

(54) Magnetic material for non-reactive process of granular perpendicular recording application

(75) Inventors: Stella Z. Wu, Fremont, CA (US); Thomas P. Nolan, Fremont, CA (US); Samuel D. Harkness, Berkeley, CA (US); Rajiv Y. Ranjan, San Jose, CA (US)

Correspondence Address: SEAGATE TECHNOLOGY c/o MOFO NOVA, 1650 TYSONS BOULEVARD, SUITE 300, MCLEAN, VA, 22102, US

(73) Assignee: SEAGATE TECHNOLOGY, Scotts Valley, CA (US)

(21) Appl. No.: 11/247,251

(22) Filed: Oct. 12, 2005

Related U.S. Application Data
(62) Division of application No. 10/698,385, filed on Nov. 3, 2003.

(51) Int. Cl. G11B 5/65; C23C 14/00

(52) U.S. Cl. 428/836.2; 204/192.15

(57) ABSTRACT

A magnetic recording medium having a substrate and a SiO₂-containing magnetic layer comprising grains is disclosed. The magnetic layer has substantial SiO₂ between the grains. This condition is achieved by sputter depositing the magnetic layer in a chamber containing a gas under vacuum. The gas contains substantially no oxygen. Such a gas is one into which no oxygen is intentionally introduced to create an oxygen-containing gas mixture but may contain a trace amount of oxygen molecules in an amount that are present in air under a similar vacuum as that of the gas in the chamber.

### FIELD OF INVENTION

The present invention relates to the recording, storage and reading of magnetic data, particularly granular perpendicular magnetic recording media having magnetic material deposited by a non-reactive process.

### BACKGROUND

Magnetic disks and disk drives are conventionally employed for storing data in magnetizable form. Preferably, one or more disks are rotated on a central axis in combination with data transducing heads positioned in close proximity to the recording surfaces of the disks and moved generally radially with respect thereto. Magnetic disks are usually housed in a magnetic disk unit in a stationary state with a magnetic head having a specific load elastically in contact with and pressed against the surface of the disk. Data are written onto and read from a rapidly rotating recording disk by means of a magnetic head transducer assembly that flies closely over the surface of the disk. Preferably, each face of each disk will have its own independent head.

In a magnetic media, digital information (expressed as combinations of “0's” and “1's”) is written on tiny magnetic bits (which themselves are made up of many even smaller grains). When a bit is written, a magnetic field produced by the disc drive's head orients the bit's magnetization in a particular direction, corresponding to either a 0 or 1. The magnetism in the head in essence “flips” the magnetization in the bit between two stable orientations.

Magnetic thin-film media, wherein a fine grained polycrystalline magnetic alloy layer serves as the active recording medium layer, are generally classified as “longitudinal” or “perpendicular,” depending on the orientation of the magnetic domains of the grains of the magnetic material. In longitudinal media (also often referred as “conventional” media), the magnetization in the bits is flipped between lying parallel and anti-parallel to the direction in which the head is moving relative to the disc. In perpendicular media, the magnetization of the disc, instead of lying in the disc's plane as it does in longitudinal recording, stands on end perpendicular to the plane of the disc. The bits are then represented as regions of upward or downward directed magnetization (corresponding to the 1's and 0's of the digital data).

FIG. 1 shows a disk recording medium and a cross section of a disc showing the difference between longitudinal and perpendicular recording. Even though FIG. 1 shows one side of the non-magnetic disk, magnetic recording layers are sputter deposited on both sides of the non-magnetic aluminum substrate of FIG. 1. Also, even though FIG. 1 shows an aluminum substrate, other embodiments include a substrate made of glass, glass-ceramic, NiP/aluminum, metal alloys, plastic/polymer material, ceramic, glass-polymer, composite materials or other non-magnetic materials.

Efforts are continually being made to increase the areal recording density, i.e., the bit density, or bits/unit area, and signal-to-medium noise ratio (SMNR) of the magnetic media. To continue pushing areal densities and increase overall storage capacity, the data bits must be made smaller and put closer together. However, there are limits to how small the bits may be made. If the bit becomes too small, the magnetic energy holding the bit in place may become so small that thermal energy may cause it to demagnetize over time. This phenomenon is known as superparamagnetism.

Perpendicular recording media are being developed for its capability of extending the areal density to a much higher level without the similar thermal stability limit that longitudinal media are facing. One of the major designs for perpendicular recording media utilizes reactive sputtering the magnetic layer in a gas mixture of oxygen and the popular inert gas Ar, to produce so called granular perpendicular media. The magnetic layer produced by this way has oxide in grain boundaries, which effectively breaks down exchange coupling and results in better recording performance.

The tendency for neighboring dipoles in a material to line up parallel or antiparallel to each other is called exchange (or exchange coupling). Basically, exchange results from the overlap of orbiting electron on adjacent atoms. The atomic moment of an atom is proportional to the angular momentum of the atom. This angular momentum consists of orbital angular momentum due to the rotation of electrons in their orbits and spin angular momentum (called “spin” for short) which is due to the rotation of electrons about their own axes. If the spin angular momentum of two electrons on neighboring atoms is s₁ and s₂, then the energy of this pair of electrons, E, is given by E=−2J s₁*s₂, where J is a constant called the exchange integral. In ferromagnetic materials, J is positive and the moments of adjacent atoms point in the same direction. In antiferromagnetic materials, J is negative. In an antiferromagnetic material, the moments of adjacent atoms point in opposite directions and, thus, there is not net macroscopic moment in the material. Still another type of exchange is called RKKY in which J varies from negative to positive or vice-versa with the thickness of the magnetic layer.

Exchange is largely a nearest-neighbor phenomenon that occurs across distances typical of the distance between atoms in a solid (a few angstroms). If there is one atomic interlayer of one material such as an oxide in grain boundaries, then that may be enough (though thicker interlayer could also be used) to break down the exchange between the grain boundaries separated by the interlayer. This breakdown in the exchange between grain boundaries allows the grains holding the data bits to be made smaller and put closer together. Thus, for the purpose of forming smaller grains, sputtering the magnetic layer in a gas mixture containing oxygen has been found to be quite useful.

However, the reactive process results in much worse uniformity in film properties due to fast oxygen consumption, as well as difficulties in process stability. Consequently, the manufacturing capability is compromised by the lack of process control as well as throughput limitation due to additional reactive gas input/stabilization and pump out time. Therefore, it is highly desirable to develop a novel magnetic material that could fulfill the similar performance without a reactive sputter process. This invention relates to a magnetic alloy design that meets such a requirement.

### SUMMARY OF THE INVENTION

This invention preferably relates a magnetic recording medium comprising a substrate and a SiO₂-containing magnetic layer comprising grains, wherein the magnetic layer has SiO₂ between the grains. Preferably, the SiO₂-containing magnetic layer is deposited on the substrate by sputter deposition in a chamber containing a gas under vacuum, wherein the gas contains substantially no oxygen, i.e., no oxygen is intentionally introduced into the gas, for example. In one embodiment, the gas is substantially pure argon. Preferably, the SiO₂-containing magnetic layer contains about 6-10% SiO₂. Also, preferably the medium has a higher SMNR than that of another medium having a same structure as that of the medium except the SiO₂-containing magnetic layer of the another medium contains about 4% SiO₂ and is sputter deposited in a chamber containing a gas mixture of argon and oxygen under vacuum. Preferably, the SiO₂-containing magnetic layer is CoCrPt—SiO₂. More preferably, the SiO₂-containing magnetic layer comprises 0-15 atomic percent Cr, 10-35 atomic percent Pt, 0.01-12 atomic percent SiO₂, and 35-90 atomic percent Co. Most preferably, the SiO₂ of the SiO₂-containing magnetic layer improves a property of the SiO₂-containing magnetic layer by segregation and de-coupling of the grains. The medium could further comprise an additional magnetic layer and optionally a non-magnetic spacer between the SiO₂-containing magnetic layer and the additional magnetic layer.

Another embodiment is a method of manufacturing a magnetic recording medium comprising obtaining a substrate and depositing a SiO₂-containing magnetic layer comprising grains, wherein the magnetic layer has SiO₂ between the grains.

Yet another embodiment is a magnetic recording medium comprising a substrate and a SiO₂-containing magnetic means comprising grains, wherein the magnetic means has SiO₂ between the grains.

Additional advantages of this invention will become readily apparent to those skilled in this art from the following detailed description, wherein only the preferred embodiments of this invention is shown and described, simply by way of illustration of the best mode contemplated for carrying out this invention. As will be realized, this invention is capable of other and different embodiments, and its details are capable of modifications in various obvious respects, all without departing from this invention. Accordingly, the drawings and description are to be regarded as illustrative in nature and not as restrictive.

### BRIEF DESCRIPTION OF THE DRAWINGS

FIG. 1 schematically shows a magnetic disk recording medium comparing longitudinal or perpendicular recording.

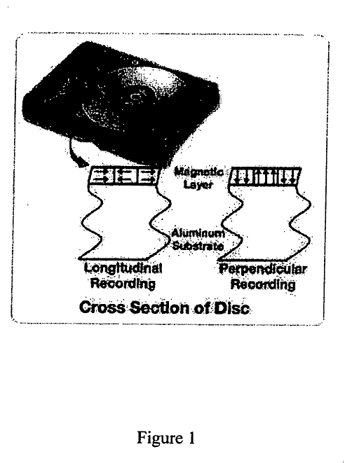

FIG. 2 is an example of the film structure of the magnetic recording media in accordance with the present invention.

FIG. 3 shows cross-sectional TEM images of microstructural profile of magnetic layers having CoCrPt—8% SiO₂ (non-oxidized) and 4% SiO₂ material (oxidized).

### DETAILED DESCRIPTION

One way to result in an improvement in the signal to noise ratio (SNR) of a magnetic recording media (for further increasing the recording density) is by decreasing the average grain volume, V. The attainable SNR increases as ˜N^{1/2} with the number of grains, N, per recorded transition as well as with decreasing Mᵣt of the recording media. Mᵣt is the product of the remanent magnetization, Mᵣ, and the film thickness, t, of the magnetic material. Both ways to increase SNR lead to a smaller energy barrier, KᵤV, which resists magnetization reversal due to thermal agitation.

The signal voltage produced by the magnetic media is proportional to Mᵣt, which contains all the media parameters. For example, in the case of a particulate media, the particles of the magnetic material are relatively apart and have low Mᵣ; hence, such a media could require a large film thickness of the magnetic layer to produce a high Mᵣt. On the other hand, a film using materials in which approximately 100% of the material is magnetic can give adequate signal voltage with even a thin film because the Mᵣt of such a film can be sufficiently large.

This invention relates to a magnetic recording medium having a substrate and a SiO₂-containing magnetic layer comprising grains. The magnetic layer has substantial SiO₂ from the target material between the grains. This condition is achieved by sputter depositing the magnetic layer in a chamber containing a gas under vacuum. The gas contains substantially no oxygen. Such a gas is one into which no oxygen is intentionally introduced to create an oxygen-containing gas mixture but may contain a trace amount of oxygen molecules in an amount that are present in air under a similar vacuum as that of the gas in the chamber.

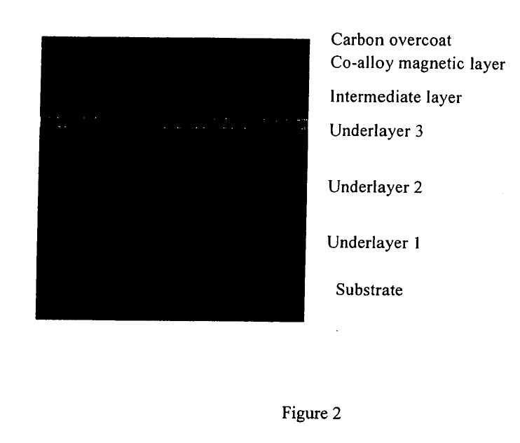

FIG. 2 shows a simplified cross-sectional view of an embodiment of this invention. All the layers were produced in a static sputter system. A more detailed film structure for a typical sample is: NiP-plated Al substrate/30 Å UL1/800 Å UL2/15 Å UL3/200 Å IL/100 Å CoCrPt—SiO₂/30 Å C. The composition of UL1 is Ti, UL2 is FeCoB, UL3 is Ag, and IL is RuCr10. The materials suitable for these underlayer/interlayer include many other candidates: for example, UL1 could be other adhesive metal material including Cr, TiCr, UL2 could be other high saturation magnetization (Bs) soft magnetic material (FeCo, CoZr, CoTa alloys with traces of other elements), UL3 could be other metallic layer having FCC, BCC or HCP crystalline structure, and IL could be another HCP material (Ru, Ru alloys, or non-magnetic Co alloys). The number of the layers shown here is also illustrative but not restrictive.

Instead of a NiP seedlayer, the layer on the substrate could be any Ni-containing seedlayer such as a NiNb seedlayer, a Cr/NiNb seedlayer, or any other Ni-containing seedlayer. Optionally, there could be an adhesion layer between the substrate and the seedlayer. The surface of the Ni-containing seedlayer could be optionally oxidized.

Embodiments of this invention include deposition of an underlayer, such as Cr or a Cr-alloy underlayer, e.g., CrMo, on the Ni-containing seedlayer. Embodiments of this invention include the use of any of the various magnetic alloys containing B, Cr and Co, such as CoCrB, CoCrPtB, CoCrNiB, CoCrNiPtB, CoCrNiTaB, CoCrNiNbB, CoCrPtTaB, CoCrPtNbB and CoCrPtTaNbB, and other combinations of B, Cr, Co, Pt, Ni, Ta and Nb, in the magnetic layer. In a preferred embodiment, the magnetic layer is Co—Cr—Pt—SiO2. In another embodiment, the Co—Cr—Pt—SiO2 comprises at least 0-15 atomic percent Cr, 10 to 35 atomic percent Pt, 0.01 to 12 atomic percent SiO₂, and Co in the balance.

In a preferred embodiment the thickness of UL1 is 10 top 100 Å, and more preferably 10 to 40 Å, the thickness of UL2 is 500 to 3000 Å, and more preferably 1000 to 2000 Å, the thickness of UL3 is 5 to 50 Å, and more preferably 10 to 30 Å, and the thickness of IL is 50 to 500 Å, and more preferably 100 to 200 Å, and the thickness of the magnetic layer is about 50 Å to about 300 Å, more preferably 80 to 150 Å. The overcoat could be hydrogenated, nitrogenated, hybrid or other forms of carbon with thickness of 20 to 80 Å, and more preferably 30 to 50 Å.

The magnetic recording medium has a remanent coercivity of about 2000 to about 10,000 Oersted, and an Mᵣt (product of remanance, Mr, and magnetic layer thickness, t) of about 0.2 to about 2.0 memu/cm². In a preferred embodiment, the coercivity is about 2500 to about 9000 Oersted, more preferably in the range of about 4000 to about 8000 Oersted, and most preferably in the range of about 4000 to about 7000 Oersted. In a preferred embodiment, the Mᵣt is about 0.25 to about 1 memu/cm², more preferably in the range of about 0.3 to about 0.7 memu/cm².

Almost all the manufacturing of a disk media takes place in clean rooms where the amount of dust in the atmosphere is kept very low, and is strictly controlled and monitored. After one or more cleaning and texturing processes on a non-magnetic substrate, the substrate has an ultra-clean surface and is ready for the deposition of layers of magnetic media on the substrate.

The apparatus for depositing all the layers needed for such media could be a static sputter system or a pass-by system, where all the layers are deposited sequentially inside a suitable vacuum environment.

Each of the layers constituting magnetic recording media of the present invention, except for a lubricant topcoat layer, may be deposited or otherwise formed by any suitable physical vapor deposition technique (PVD), e.g., sputtering, or by a combination of PVD techniques, i.e., sputtering, vacuum evaporation, etc., with sputtering being preferred. The lubricant layer is typically provided as a topcoat by dipping of the medium into a bath containing a solution of the lubricant compound, followed by removal of excess liquid, as by wiping, or by a vapor lube deposition method.

Sputtering is perhaps the most important step in the whole process of creating recording media. There are two types of sputtering: pass-by sputtering and static sputtering. In pass-by sputtering, disks are passed inside a vacuum chamber, where they are bombarded with the magnetic and non-magnetic materials that are deposited as one or more layers on the substrate. Static sputtering uses smaller machines, and each disk is picked up and sputtered individually. The layers on the disk of FIG. 2 were deposited by static sputtering.

The sputtering layers are deposited in what are called bombs, which are loaded onto the sputtering machine. The bombs are vacuum chambers with targets on either side. The substrate is lifted into the bomb and is bombarded with the sputtered material.

Sputtering leads to some particulates formation on the post sputter disks. These particulates need to be removed to ensure that they do not lead to the scratching between the head and substrate. Thus, a lube is preferably applied to the substrate surface as one of the topcoat layers on the substrate.

Once a lube is applied, the substrates move to the buffing/burnishing stage, where the substrate is polished while it preferentially spins around a spindle. After buffing/burnishing, the substrate is wiped and a clean lube is evenly applied on the surface.

Subsequently, the disk is prepared and tested for quality thorough a three-stage process. First, a burnishing head passes over the surface, removing any bumps (asperities as the technical term goes). The glide head then goes over the disk, checking for remaining bumps, if any. Finally the certifying head checks the surface for manufacturing defects and also measures the magnetic recording ability of the substrate.

### EXAMPLES

Table 1 shows the magnetic properties measured by Kerr Looper on a medium sample made with CoCr6Pt18SiO28 alloy sputtered in pure Ar, therefore, a non-reactive sputter process. The Kerr loop is fully squared with coercivity in the range that is suitable for high density recording.

TABLE 1
The magnetic properties for a sample with
CoCr6Pt18SiO₂8 alloy sputtered in substantially
pure Ar (wherein a trace amounts of impurities
could be present), but with no substantial
oxygen, measured by Kerr Looper.

| Side | Hc | Hn | S | S* |
|---|---|---|---|---|
| A | 4.240 | 2.229 | 1.026 | 0.513 |
| B | 4.417 | 2.098 | 1.020 | 0.464 |

Table 2 lists the recording performance characteristics of the sample whose magnetic properties are shown in Table 1, together with reference samples (References 1 and 2). Reference 1 had CoCr6Pt18SiO₂4 magnetic alloy sputtered in an environment containing a Ar and O₂ gas mixture, therefore, a reactive oxidation process. Reference 2 had CoCr6Pt18SiO₂4 magnetic alloy sputtered in a Ar without O₂, therefore, a non-reactive oxidation process. The measurement was performed on a Guzik tester at 500 kfci linear density and 5400 rpm.

TABLE 2
Recording data of three samples made with 8% SiO2 and non-reactive
process, and 4% SiO2 with non-reactive and reactive processes.

| | Mrt | LF | MF | Mod | OW | PW50 | SMNR(f) |
|---|---|---|---|---|---|---|---|
| | (memum/cm2 | (μVpp) | (μVpp) | (%) | (dB) | (μinch) | (dB) |
| sample (8% SiO2 w/o oxygen) | 0.67 | 2582.6 | 2417.2 | 5.4 | 75.7 | 2.4 | 14.9 |
| reference 1 (4% SiO2 w/o oxygen) | 0.91 | 3036.4 | 2998.5 | 9.9 | 32.0 | 2.7 | 11.5 |
| reference 2 (4% SiO2 with oxygen) | 0.79 | 2581.1 | 2354.3 | 6.4 | 68.1 | 2.5 | 13.9 |

By comparing the SMNR values of References 1 and 2 in Table 2, one finds that the presence of oxygen in the sputtering chamber, which results in the formation of oxide between the grains, improves SMNR given that the other parameters including the concentrations of SiO₂ in the magnetic layers are substantially the same at about 4%. On the other hand, it was found that increasing the SiO₂ content in the magnetic layer from 4% to 8% while still maintaining a substantially no oxygen environment in the deposition chamber during sputtering of the magnetic layer increases the SMNR value to beyond that of Reference 2, which refers to a magnetic layer containing 4% SiO₂ and sputtered in an environment containing a Ar and O₂ gas mixture.

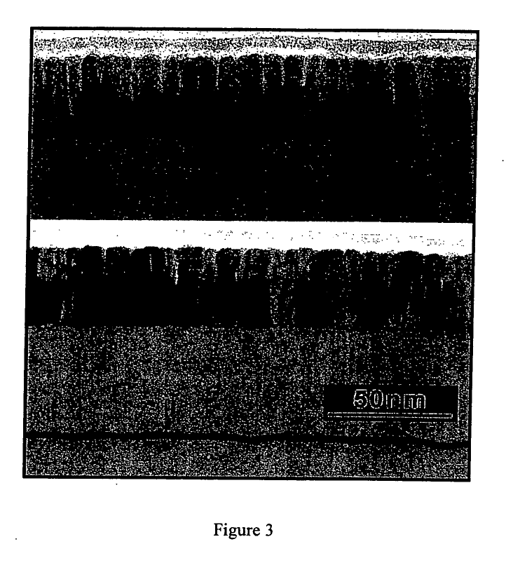

FIG. 3 shows the cross-sectional TEM images of the sample having CoCr6Pt18SiO₂8 alloy sputtered in substantially pure Ar with substantially no oxygen (top structure) and of Reference 2 (bottom structure). The excellent microstructural profile for CoCrPt—8% SiO₂ is clearly seen as compared to the 4% SiO2 material sputtered in an oxygen-containing environment.

The addition of SiO₂ improves the performance of the CoCrPt magnetic alloy films by effective segregation and grain de-coupling. With sufficient SiO₂ in the magnetic alloy, no reactive oxidation process is needed thereby producing a huge benefit in process control as well as manufacturability.

Summarizing this invention, Cr should be in the atomic range of 0-15%, preferably 5-8% in the magnetic layer; Pt should be in the range of 10-35%, preferably 15-25%, and SiO₂ should be 0.01-12%, preferably 6-10%; Co makes up the balance. The substrate being used could be Al dominated conductive type, or glass, glass ceramic type, with optional numbers of underlayer, and/or intermediate layer below the magnetic layer, suitable to establish the perpendicular easy axis orientation and grain structure.

In addition, the magnetic layer could contain at least one more element from a collection of B, Ta, Nb, Ni, Ti, Al, Si, Mo, Zr, etc. The magnetic layer for storage could be single layers, or multiple adjacent layers, or laminated structure with thin non-magnetic spacing.

This application discloses several numerical ranges in the text and figures. The numerical ranges disclosed support any range or value within the disclosed numerical ranges even though a precise range limitation is not stated verbatim in the specification because this invention can be practiced throughout the disclosed numerical ranges.

The above description is presented to enable a person skilled in the art to make and use the invention, and is provided in the context of a particular application and its requirements. Various modifications to the preferred embodiments will be readily apparent to those skilled in the art, and the generic principles defined herein may be applied to other embodiments and applications without departing from the spirit and scope of the invention. Thus, this invention is not intended to be limited to the embodiments shown, but is to be accorded the widest scope consistent with the principles and features disclosed herein. Finally, the entire disclosure of the patents and publications referred in this application are hereby incorporated herein by reference.

1-10. (canceled)

11. A method of manufacturing a magnetic recording medium comprising obtaining a substrate and depositing a SiO₂-containing magnetic layer comprising grains, wherein the magnetic layer has SiO₂ between the grains, wherein the SiO₂-containing magnetic layer is deposited on the substrate by sputter deposition in a chamber containing a gas under vacuum, wherein the gas contains substantially no oxygen.

12. (canceled)

13. The method of claim 11, wherein no oxygen is intentionally introduced into the gas.

14. The method of claim 11, wherein the SiO₂-containing magnetic layer contains about 6-10% SiO₂.

15. The method of claim 11, wherein the gas is substantially pure argon.

16. The method of claim 11, wherein the SiO₂-containing magnetic layer is CoCrPt—SiO₂.

17. The method of claim 11, wherein the SiO₂-containing magnetic layer comprises 0-15 atomic percent Cr, 10-35 atomic percent Pt, 0.01-12 atomic percent SiO₂, and 35-90 atomic percent Co.

18. The method of claim 11, wherein SiO₂ of the SiO₂-containing magnetic layer improves a performance of the SiO₂-containing magnetic layer by segregation and de-coupling of the grains.

19. The method of claim 11, further comprising an additional magnetic layer and optionally a non-magnetic spacer between the SiO₂-containing magnetic layer and the additional magnetic layer.

20. (canceled)
